(19) United States
(12) Patent Application Publication
(10) Pub. No.: US 2023/0054903 A1
(43) Pub. Date: Feb. 23, 2023

(54) JOINT STRUCTURE OF RESIN MEMBERS, RESIN HOUSING OF ELECTRICAL EQUIPMENT, AND LASER WELDING METHOD

(71) Applicant: Mitsubishi Electric Corporation, Chiyoda-ku, Tokyo (JP)

(72) Inventor: Takashi OHARA, Tokyo (JP)

(73) Assignee: Mitsubishi Electric Corporation, Chiyoda-ku, Tokyo (JP)

(21) Appl. No.: 17/792,518

(22) PCT Filed: Apr. 27, 2020
(86) PCT No.: PCT/JP2020/017900

§ 371 Date: Jul. 13, 2022

(51) Int. Cl. B29C 65/16

(52) U.S. Cl. CPC B29C 65/1635

(57) ABSTRACT

A first resin member having laser light absorbing property and a second resin member having laser light transmitting property are joined together through laser welding. A pressure application step of applying pressures to contact boundary surfaces of the first resin member and the second resin member in upward and downward directions includes warping, along a first welding portion, a one end portion side of the second resin member such that the warping occurs from a follow-up origin at a boundary between a thin portion and a thick base portion of the second resin member. Consequently, a gap between the contact boundary surfaces that is generated owing to a curved recess in the first welding portion can be eliminated, whereby imperfection of welding is ameliorated.

### CROSS REFERENCE TO RELATED APPLICATIONS

This application is a National Stage of International Application No. PCT/JP2020/017900, filed on Apr. 27, 2020.

### TECHNICAL FIELD

The present disclosure relates to a resin member joint structure, a resin housing of electrical equipment, and a laser welding method.

### BACKGROUND ART

Conventionally, laser welding has been known as a means for joining together resin members. In laser welding, a transmitting resin member having laser light transmitting property and an absorbing resin member having laser light absorbing property are superposed on each other, and laser light is applied to contact boundary surfaces of the members from the transmitting resin member side, whereby both members are melted and welded together.

At this time, if there is a gap between the contact boundary surfaces of both members, heat generated from a surface of the absorbing resin member is less likely to be transmitted to the transmitting resin member. Consequently, the transmitting resin member is insufficiently melted upon heating. Thus, the absorbing resin member and the transmitting resin member are not sufficiently welded together, whereby imperfection of welding such as deficiency in joining strength is caused.

In conventional laser welding methods, laser light is applied in a state where pressures are applied to the resin members in upward and downward directions in order to eliminate a gap between both members. Further, in Patent Document 1, laser light is applied with a transmitting resin member and a non-transmitting resin member being in pressure contact with each other in a state where at least one of contact surface portions forming contact boundary surfaces of the transmitting resin member and the non-transmitting resin member is heated to be softened in advance.

### CITATION LIST

### Patent Document

Patent Document 1: Japanese Laid-Open Patent Publication No. 2004-188802

### SUMMARY OF THE INVENTION

### Problems to be Solved by the Invention

However, the conventional laser welding methods do not take into account the rigidities of the resin members to be welded together. For example, if the transmitting resin member has a large plate thickness and is excessively rigid, a welding surface of the transmitting resin member is not fitted along a welding surface of the absorbing resin member even by applying pressures to both members in the upward and downward directions. Consequently, a problem arises in that the gap is not eliminated, whereby imperfection of welding occurs.

Further, the method disclosed in Patent Document 1 is required to include, as a step of softening the contact surface portions in advance, a separate step such as a step of, for example, applying laser light for preliminary heating, causing contact with a heat plate which is a heating member, or causing warm air to blow. Consequently, a problem arises in that the process is complicated.

The present disclosure has been made to solve the above problems, and an object of the present disclosure is to provide a resin member joint structure and a laser welding method that enable amelioration of imperfection of welding.

Another object of the present disclosure is to achieve improvement in the quality of a resin housing of electrical equipment by ameliorating imperfection of welding in the resin member joint structure.

### Solution to the Problems

A resin member joint structure according to the present disclosure is a resin member joint structure in which a first resin member and a second resin member have been joined together through welding. The first resin member includes a first welding portion. The second resin member includes a plate-shaped portion which has two main surfaces opposite to each other. A second welding portion joined to the first welding portion is located at one end portion of one main surface out of the main surfaces. A follow-up origin is provided on one or each of the two main surfaces of the second resin member such that, from the follow-up origin, the one end portion side on which the second welding portion is located is warped along the first welding portion.

Another resin member joint structure according to the present disclosure is a resin member joint structure in which a first resin member and a second resin member have been joined together through welding. The first resin member includes, on one end portion thereof, a rib projecting in a direction toward the second resin member, and includes a first welding portion at a top portion of the rib. The second resin member includes a plate-shaped portion which has two main surfaces opposite to each other. A second welding portion joined to the first welding portion is located at one end portion of one main surface out of the main surfaces.

A resin housing of electrical equipment according to the present disclosure has the resin member joint structure according to the present disclosure, the resin housing including: the first resin member; and the second resin member, wherein electrical equipment is accommodated.

A laser welding method according to the present disclosure is a laser welding method for joining together a first resin member having laser light absorbing property and a second resin member having laser light transmitting property through laser welding, the laser welding method including: a contact step of preparing the first resin member including a first welding portion and the second resin member including a plate-shaped portion which has two main surfaces opposite to each other, and placing, on an upper side of the first welding portion, a second welding portion located at one end portion of one main surface out of the main surfaces of the second resin member, to bring the second welding portion into contact with the upper side; a pressure application step of applying pressures to contact boundary surfaces of the first welding portion and the second welding portion in upward and downward directions; and a laser light application step of applying laser light to the first welding portion from the second resin member side, to weld the first welding portion to the second welding portion. The pressure application step includes warping, along the first welding portion, the one end portion side of the second resin member such that the warping occurs from a follow-up origin provided on one or each of the two main surfaces, to eliminate a gap between the contact boundary surfaces.

### Effect of the Invention

In the resin member joint structure according to the present disclosure, the follow-up origin is provided on the second resin member so that the one end portion side of the second resin member on which the second welding portion is located is warped along the first welding portion of the first resin member. Consequently, the gap between the contact boundary surfaces of the first welding portion and the second welding portion can be eliminated, whereby imperfection of welding can be ameliorated.

In addition, the top portion of the rib projecting from the one end portion of the first resin member is used as the first welding portion so that the width of the first welding portion can be decreased. Thus, the one end portion side of the second resin member on which the second welding portion is located, is easily fitted along the first welding portion of the first resin member. Thus, the gap between the contact boundary surfaces of the first welding portion and the second welding portion can be eliminated, whereby imperfection of welding can be ameliorated.

In addition, in the resin housing of electrical equipment according to the present disclosure, imperfection of welding can be ameliorated, whereby quality improvement is achieved.

In addition, in the laser welding method according to the present disclosure, the pressure application step includes warping, along the first welding portion, the one end portion side of the second resin member such that the warping occurs from the follow-up origin, to eliminate the gap between the contact boundary surfaces. Consequently, imperfection of welding can be ameliorated.

Objects, features, aspects, and effects of the present disclosure other than those described above will become more apparent from the following detailed description with reference to the drawings.

### BRIEF DESCRIPTION OF THE DRAWINGS

FIG. 1 is a cross-sectional view showing a resin member joint structure according to embodiment 1.

FIG. 2A to 2D are side views for explaining a laser welding method according to embodiment 1.

FIG. 3A to 3D are cross-sectional views for explaining the laser welding method according to embodiment 1.

FIGS. 4A and 4B are diagrams for explaining imperfection of welding due to conventional laser welding.

FIG. 5A to 5B are diagrams showing a resin member joint structure according to embodiment 2.

FIG. 6 is a cross-sectional view showing a resin member joint structure according to embodiment 3.

FIG. 7A to 7 7D are cross-sectional views for explaining a laser welding method according to embodiment 3.

FIG. 8A to 8C are cross-sectional views showing modifications of the resin member joint structure according to embodiment 3.

FIG. 9 is a cross-sectional view showing a resin member joint structure according to embodiment 4.

FIG. 10A to 10D are cross-sectional views for explaining a laser welding method according to embodiment 4.

FIG. 11 is a cross-sectional view showing a resin member joint structure according to embodiment 5.

FIG. 12A to 12D are cross-sectional views for explaining a laser welding method according to embodiment 5.

FIG. 13A to 13E are cross-sectional views showing modifications of the resin member joint structure according to embodiment 5.

FIG. 14A is a perspective view and FIG. 14B is a partial cross-sectional view showing a box-shaped resin housing according to embodiment 6.

FIG. 15A is a perspective view and FIG. 15B is a partial cross-sectional view showing a box-shaped resin housing according to embodiment 6.

FIG. 16A is a perspective view and FIG. 16B is a partial cross-sectional view showing a box-shaped resin housing according to embodiment 6.

FIG. 17A is a perspective view and FIG. 17B is a partial cross-sectional view showing a box-shaped resin housing according to embodiment 6.

FIG. 18A is a perspective view and FIG. 18B is a partial cross-sectional view showing a box-shaped resin housing according to embodiment 6.

FIG. 19 is a cross-sectional view showing a resin housing of electrical equipment according to embodiment 6.

### DESCRIPTION OF EMBODIMENTS

### Embodiment 1

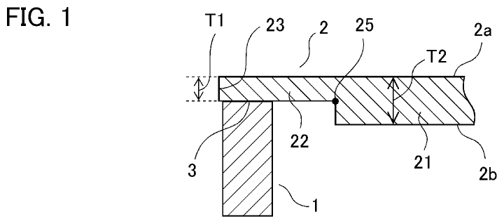

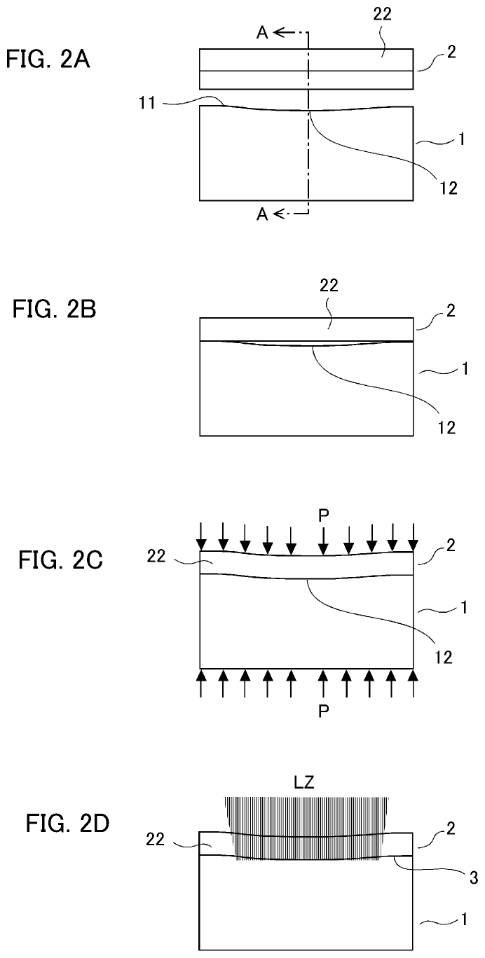

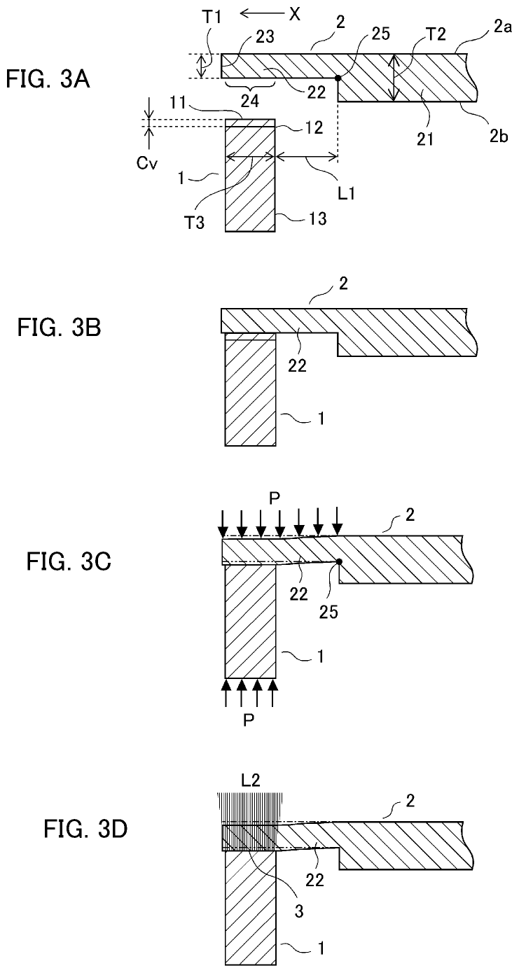

Hereinafter, a resin member joint structure and a laser welding method according to embodiment 1 will be described with reference to the drawings. FIG. 1 is a cross-sectional view showing the resin member joint structure according to embodiment 1. FIGS. 2A to 2D and FIGS. 3A to 3D are respectively a side view and a cross-sectional view for explaining the laser welding method according to embodiment 1. FIG. 3A is a cross-sectional view taken at a position indicated by A-A in FIG. A. In the drawings, the same and corresponding portions are denoted by the same reference characters.

A first resin member 1 and a second resin member 2 are joined together through laser welding. The first resin member 1 has laser light absorbing property, and the second resin member 2 has laser light transmitting property. The first resin member 1 and the second resin member 2 are not particularly limited in terms of uses thereof and are used for, for example, forming a box-shaped housing in which an electrical part is accommodated.

As shown in FIG. 1, the first resin member 1 is in contact with one end portion on an end surface 23 side of the second resin member 2, and contact boundary surfaces 3 of the resin members are joined portions. As shown in FIG. 3A, the first resin member 1 includes a first welding portion 11 at one end portion thereof. The second resin member 2 includes a plate-shaped portion 21 which has two main surfaces 2a and 2b opposite to each other. A second welding portion 24 joined to the first welding portion 11 is located at one end portion of one main surface 2b out of the main surfaces.

A follow-up origin 25 is provided on one or each of the two main surfaces 2a and 2b of the second resin member 2 such that, from the follow-up origin 25, the one end portion side on which the second welding portion 24 is located is warped along the first welding portion 11. In embodiment 1, the second resin member 2 includes, on the one end portion side of the plate-shaped portion 21, a thin portion 22 having a plate thickness smaller than the plate thickness of another portion (referred to as a thick base portion) of the plate-shaped portion 21. The second welding portion 24 is located in the thin portion 22, and the follow-up origin 25 is present at a boundary between the thin portion 22 and the thick base portion of the plate-shaped portion 21.

Dimensions of respective portions of the resin member joint structure according to embodiment 1, e.g., the ratio between the plate thickness of the thin portion 22 and the plate thickness of the thick base portion of the plate-shaped portion 21, the distance from the follow-up origin 25 to the first resin member 1, the width of the first welding portion 11, and the like, are not particularly limited and are determined as appropriate on the basis of the rigidity of the second resin member 2, the shape and required strength of a box-shaped housing, and the like.

Meanwhile, a follow-up capability exhibited when the second resin member 2 is fitted along the first welding portion 11 from the follow-up origin 25, is improved by satisfying some of the conditions presented below. First, the second resin member 2 is configured as a cantilever beam having a free end on the end surface 23 side. A warp amount σ1 obtained when the cantilever beam has received a uniformly distributed load is obtained with the following expression 1. A warp amount σ2 obtained when a both-ends-supported beam has received a uniformly distributed load is obtained with the following expression 2.

σ1=wL⁴/8EI (expression 1)

σ2=5wL⁴/384EI (expression 2)

In each of expression 1 and expression 2, “w” represents the uniformly distributed load, “L” represents the length of the corresponding one of the cantilever beam and the both-ends-supported beam, “E” represents a Young's modulus, and “I” represents a second moment of area. A second moment of area indicates an extent of difficulty to bend the material, and a higher second moment of area leads to a higher extent of difficulty to bend the material. According to expression 1 and expression 2, the warp amount σ1 of the cantilever beam becomes 9.6-fold as compared to the warp amount σ2 of the both-ends-supported beam. Thus, if the second resin member 2 is configured as a cantilever beam, the follow-up capability thereof becomes 9.6-fold.

Further, according to expression 1, the warp amount σ1 is proportional to the fourth power of the length L of the cantilever beam. Thus, the follow-up origin 25 is desirably located apart from an inner end surface 13 of the first resin member 1 by at least the width of the first welding portion 11.

Therefore, if, in a plane parallel to the main surfaces 2a and 2b of the second resin member 2, a direction from the center side of the second resin member 2 toward the one end portion side on which the second welding portion 24 is located is defined as an X direction, the distance from the follow-up origin 25 to the inner end surface 13 of the first resin member 1 is defined as L1, and the width in the X direction of the first welding portion 11 is defined as T3 as shown in FIG. 3A, L1≥T3 is satisfied. Consequently, the follow-up capability becomes equal to or greater than 16-fold.

The second moment of area I of a member having a cross section with a rectangular shape is obtained by the following expression 3. In expression 3, “b” represents the width of the rectangular shape, and “h” represents the height thereof. As indicated by expression 3, the second moment of area is proportional to the third power of the height h.

I=bh³/12 (expression 3)

Thus, if the plate thickness of the thin portion 22 is defined as T1 and the plate thickness of the thick base portion of the plate-shaped portion 21 is defined as T2 as shown in FIG. 3A, T1≤T2×2/3 is satisfied. Consequently, a second-moment-of-area ratio is 3³/2³, and the follow-up capability of the thin portion 22 becomes 3.4-fold as compared to the follow-up capability of the thick base portion. By satisfying the above three conditions, an advantageous effect of about 528-fold improvement in the follow-up capability is obtained, and an advantageous effect of decreasing the gap between the contact boundary surfaces 3 can be expected to be obtained.

The laser welding method according to embodiment 1 will be described with reference to FIGS. 2A to 2D and FIGS. 3A to 3D. As shown in FIG. 2A and FIG. 3A, the first resin member 1 including the first welding portion 11 at the one end portion thereof, and the second resin member 2 including the plate-shaped portion 21 which has the two main surfaces 2a and 2b opposite to each other, are prepared. Here, a curved recess 12 having a dimension Cv is assumed to be present in a surface of the first welding portion 11.

The second resin member 2 includes, on the one end portion side of the plate-shaped portion 21, the thin portion 22 having a plate thickness smaller than the plate thickness of the thick base portion of the plate-shaped portion 21. The second welding portion 24 is located in the thin portion 22. Next, as shown in FIG. 2B and FIG. 3B, the second welding portion 24 of the second resin member 2 is disposed on the upper side of the first welding portion 11, to be brought into contact with the said upper side (contact step).

Subsequently, as shown in FIG. 2C and FIG. 3C, pressures are applied to the contact boundary surfaces of the first welding portion 11 and the second welding portion 24 in upward and downward directions (pressure application step). Arrows denoted by P in the drawings indicate the pressures. In the pressure application step, the one end portion side of the second resin member 2 is warped along the first welding portion 11 from the follow-up origin 25 at the boundary between the thin portion 22 and the thick base portion of the second resin member 2 so that the gap between the contact boundary surfaces that is generated owing to the curved recess 12 in the first welding portion 11 is eliminated.

Finally, as shown in FIG. 2D and FIG. 3D, laser light is applied from the second resin member 2 side to the first welding portion 11 so that the first welding portion 11 is welded to the second welding portion 24 (laser light application step). LZ in the drawing indicates the laser light. Since there is no gap between the contact boundary surfaces 3 of the first welding portion 11 and the second welding portion 24, heat of the laser light is transmitted to the second welding portion 24, whereby normal welding can be performed.

It is noted that the type of the laser light used in the laser light application step is not particularly limited and is determined on the basis of the absorption spectrum, the plate thickness, and the like of the second resin member 2 allowing the laser light to be transmitted therethrough. For example, laser light from a YAG laser, a neodymium YAG laser, a helium-neon laser, a semiconductor laser, or the like is used.

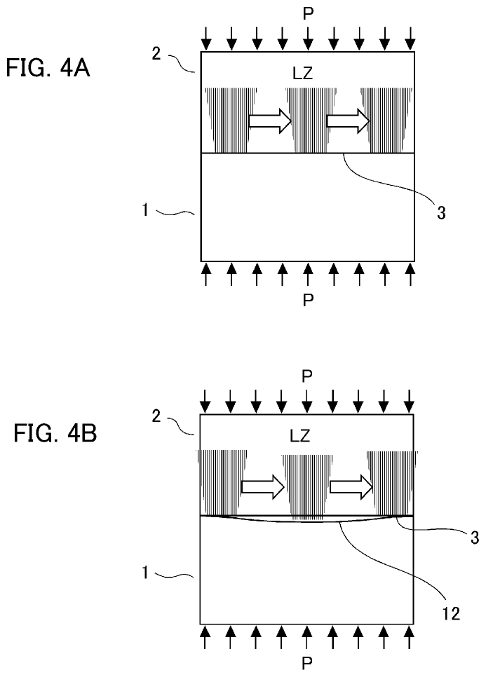

Imperfection of welding due to conventional laser welding will be described with reference to FIGS. 4A and 4B. FIG. 4A illustrates the case where no curved recess is present in the first welding portion. FIG. 4B illustrates the case where the curved recess is present in the first welding portion. In the case where no curved recess is present in the first welding portion of the first resin member 1 as shown in FIG. 4A, no gap is generated between the contact boundary surfaces 3 when pressures are applied to the contact boundary surfaces 3 in the upward and downward directions in the pressure application step. Consequently, heat of the laser light is transmitted to the second resin member 2, whereby normal welding can be performed.

Meanwhile, in the case where the curved recess 12 is present in the first welding portion of the first resin member 1 as shown in FIG. 4B, if the second resin member 2 has a small plate thickness and a low rigidity, pressure application enables the second resin member 2 to be fitted along the curved recess 12. However, if the second resin member 2 has a large plate thickness and a high rigidity, the second resin member 2 is not fitted along the curved recess 12 and a gap is generated between the contact boundary surfaces 3 even when pressures are applied to the contact boundary surfaces 3 in the upward and downward directions. Consequently, heat of the laser light is not transmitted to the second resin member 2, whereby imperfection of welding occurs.

In embodiment 1, even if the plate-shaped portion 21 of the second resin member 2 has a large plate thickness T2 and a high rigidity, the rigidity of the one end portion side can be decreased since the thin portion 22 is provided on the one end portion side. In addition, the one end portion side of the second resin member 2 is warped along the first welding portion 11 from the follow-up origin 25 at the boundary between the thin portion 22 and the thick base portion of the plate-shaped portion 21. Thus, the gap between the contact boundary surfaces 3 can be eliminated. Therefore, the resin member joint structure and the laser welding method according to embodiment 1 enable amelioration of imperfection of welding.

### Embodiment 2

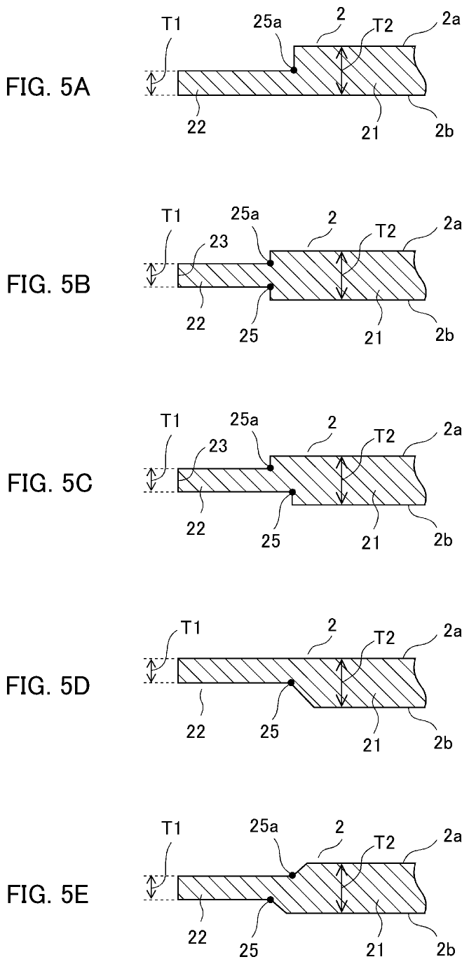

In embodiment 2, modifications of the resin member joint structure according to the above embodiment 1 will be described with reference to FIGS. 5A to 5E. One or more follow-up origins 25 only have to be provided on one or each of the two main surfaces 2a and 2b of the second resin member 2. Thus, various modifications are conceived depending on the arrangement of the thin portion 22.

In FIG. 5A, a thin portion 22 is formed by decreasing the thickness on the main surface 2a side of the plate-shaped portion 21, and a follow-up origin 25a is provided on the upper side of the second resin member 2. In each of FIG. 5B and FIG. 5C, a thin portion 22 is formed by decreasing the thicknesses at both sides of the main surfaces 2a and 2b, and two follow-up origins 25a and 25 are provided on the upper side and the lower side of the second resin member 2.

In FIG. 5B, the distances from the end surface 23 of the second resin member 2 to the two follow-up origins 25a and 25 are equal to each other. Meanwhile, in FIG. 5C, the distances from the end surface 23 of the second resin member 2 to the follow-up origins 25a and 25 are different from each other. By thus shifting the positions of the follow-up origins 25a and 25 from each other, the strengths of portions around the follow-up origins 25a and 25 can be ensured.

In FIG. 5D, a tapered portion is provided such that the plate thickness between the thin portion 22 and the thick base portion continuously changes. In the example shown in FIG. 5E, the two follow-up origins 25a and 25 are provided on the upper side and the lower side with the positions thereof being shifted from each other, and tapered portions are provided between the thin portion 22 and the thick base portion. By providing such a tapered portion, the strength of a portion around the follow-up origin 25 is improved.

In embodiment 2, the same advantageous effects as those in the above embodiment 1 are obtained, and a resin member joint structure can be provided according to the rigidity of the second resin member 2, and the shape and the required strength of a box-shaped housing.

### Embodiment 3

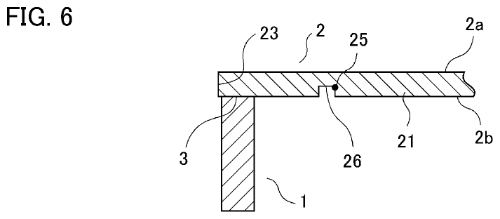

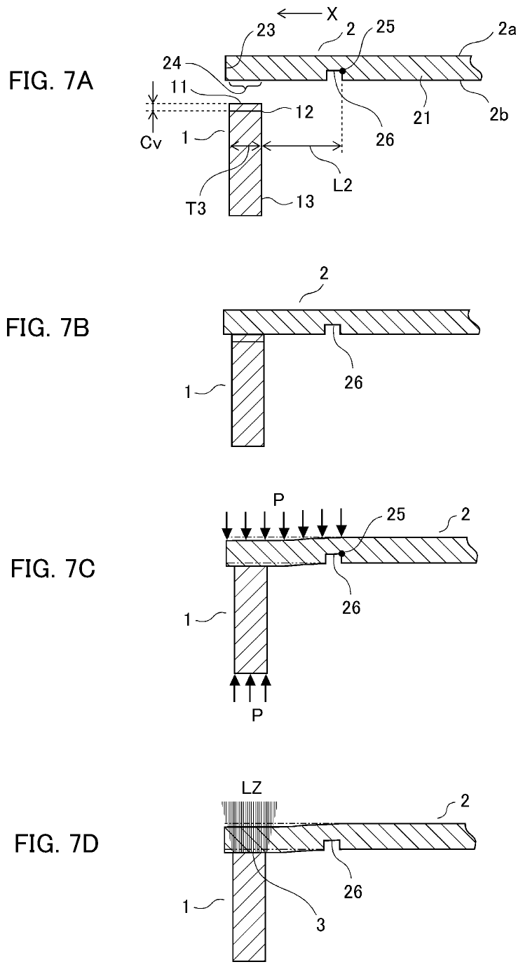

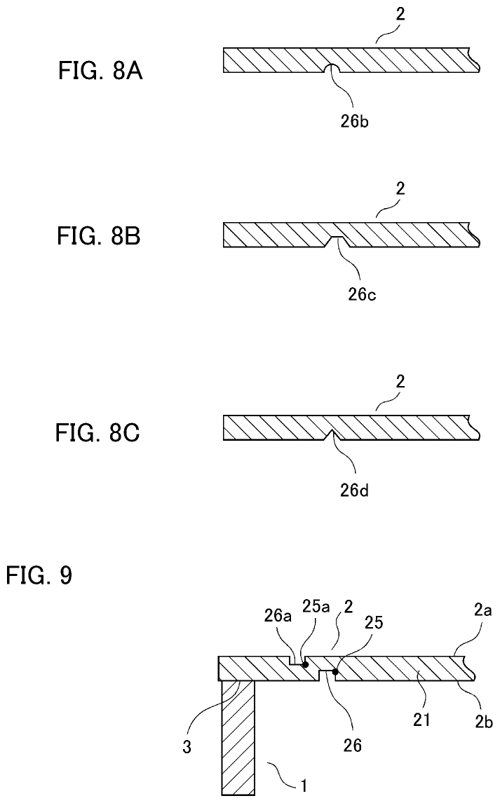

FIG. 6 is a cross-sectional view showing a resin member joint structure according to embodiment 3. FIGS. 7A to 7D are cross-sectional views for explaining a laser welding method according to embodiment 3. FIGS. 8A to 8C are cross-sectional views showing modifications of the resin member joint structure according to embodiment 3. In embodiment 3, a method for providing the follow-up origin 25 without forming the thin portion 22 in the second resin member 2 will be described.

In embodiment 3, the second resin member 2 includes a recess groove 26 in one or each of the two main surfaces 2a and 2b of the plate-shaped portion 21, and the follow-up origin 25 is present inside the recess groove 26. The plate thickness of the plate-shaped portion 21 of the second resin member 2 in embodiment 3 is smaller than the plate thickness of the thick base portion in the above embodiment 1. Thus, even if the thin portion 22 is not formed in order to decrease the rigidity, warping can be performed by using the recess groove 26.

The position of the recess groove 26 is not particularly limited as long as the recess groove 26 is located at a position that is farther from the one end portion than the second welding portion 24 is. Meanwhile, the follow-up capability exhibited when the second resin member 2 is fitted along the first welding portion 11 from the follow-up origin 25, is improved by satisfying the conditions described below.

As described in the above embodiment 1, the warp amount σ1 is proportional to the fourth power of the length L of the cantilever beam. Thus, the follow-up origin 25 is desirably located apart from the inner end surface 13 of the first resin member 1 by at least the width of the first welding portion 11. Therefore, if, in the plane parallel to the main surfaces 2a and 2b of the second resin member 2, a direction from the center side of the second resin member 2 toward the one end portion side on which the second welding portion 24 is located is defined as an X direction, the distance from the follow-up origin 25 to the inner end surface 13 of the first resin member 1 is defined as L2, and the width in the X direction of the first welding portion 11 is defined as T3 as shown in FIG. 7A, L2≥T3 is satisfied. Consequently, the follow-up capability becomes equal to or greater than 16-fold.

The laser welding method according to embodiment 3 will be described with reference to FIGS. 7A to 7D. As shown in FIG. 7A, the first resin member 1 including the first welding portion 11 at the one end portion thereof, and the second resin member 2 including the plate-shaped portion 21 which has the two main surfaces 2a and 2b opposite to each other, are prepared. Here, the curved recess 12 having the dimension Cv is assumed to be present in the surface of the first welding portion 11.

Next, as shown in FIG. 7B, the second welding portion 24 of the second resin member 2 is disposed on the upper side of the first welding portion 11, to be brought into contact with the said upper side (contact step). Subsequently, as shown in FIG. 7C, pressures are applied to the contact boundary surfaces of the first welding portion 11 and the second welding portion 24 in the upward and downward directions (pressure application step).

In the pressure application step, the one end portion side of the second resin member 2 is warped along the first welding portion 11 from the follow-up origin 25 inside the recess groove 26 provided in the main surface 2b of the second resin member 2 so that the gap between the contact boundary surfaces that is generated owing to the curved recess 12 in the first welding portion 11 is eliminated. Finally, as shown in FIG. 7D, laser light is applied from the second resin member 2 side to the first welding portion 11 so that the first welding portion 11 is welded to the second welding portion 24 (laser light application step). Since there is no gap between the contact boundary surfaces 3 of the first welding portion 11 and the second welding portion 24, heat of the laser light is transmitted to the second welding portion 24, whereby normal welding can be performed.

It is noted that the cross-sectional shape of the recess groove 26 is not limited to a substantially rectangular shape, and the recess groove 26 may be a recess groove 26b having a substantially semicircular shape as shown in FIG. 8A, a recess groove 26c having a substantially trapezoidal shape as shown in FIG. 8B, or a recess groove 26d having a substantially triangular shape as shown in FIG. 8C. A shape, a size, and the like of the recess groove 26 can be selected as appropriate according to use of a box-shaped housing, ease of machining, or the like.

In embodiment 3, if the plate thickness of the plate-shaped portion 21 of the second resin member 2 is smaller than the plate thicknesses in the above embodiments 1 and 2, the follow-up origin 25 can be provided and the same advantageous effects as those in the above embodiment 1 are obtained, without forming the thin portion 22.

### Embodiment 4

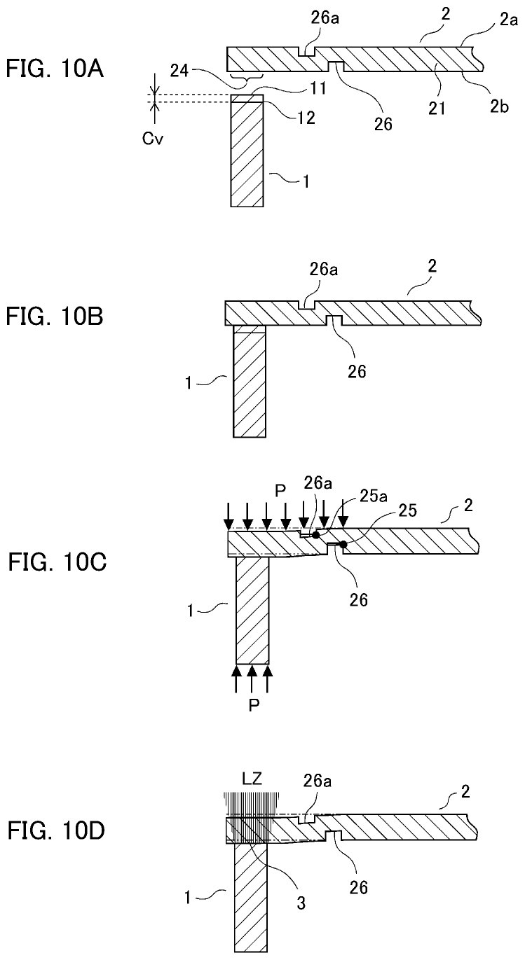

FIG. 9 is a cross-sectional view showing a resin member joint structure according to embodiment 4. FIGS. 10A to 10D are cross-sectional views for explaining a laser welding method according to embodiment 4. In embodiment 4, a modification of the resin member joint structure according to the above embodiment 3 will be described. One or more follow-up origins 25 only have to be provided on one or each of the two main surfaces 2a and 2b of the second resin member 2. Thus, various modifications are conceived depending on the arrangement of the recess groove 26.

In embodiment 4, as shown in FIG. 9, the plate-shaped portion 21 of the second resin member 2 is provided with: the recess groove 26 in the one main surface 2b; and a recess groove 26a in the other main surface 2a. The follow-up origins 25 and 25a are respectively present inside the two recess grooves 26 and 26a. The recess groove 26a in the main surface 2a is provided at a position that is closer to the second welding portion than the recess groove 26 in the main surface 2b is. By thus shifting the positions of the plurality of recess grooves 26 and 26a from each other, it is possible to improve the follow-up capability of the second resin member 2 while ensuring the strength thereof.

Although the recess grooves 26a and 26 are respectively provided in the two main surfaces 2a and 2b in FIG. 9, the recess groove may be provided at each of two or more positions in either one of the two main surfaces 2a and 2b. For example, two recess grooves 26 may be provided in the one main surface 2b. By increasing the number of the recess grooves, the second resin member 2 comes to have a low rigidity and is easily warped. Consequently, the follow-up capability is improved.

The laser welding method according to embodiment 4 will be described with reference to FIGS. 10A to 10D. As shown in FIG. 10A, the first resin member 1 including the first welding portion 11 at the one end portion thereof, and the second resin member 2 including the plate-shaped portion 21, are prepared. Here, the curved recess 12 having the dimension Cv is assumed to be present in the surface of the first welding portion 11. Next, as shown in FIG. 10B, the second welding portion 24 of the second resin member 2 is disposed on the upper side of the first welding portion 11, to be brought into contact with the said upper side (contact step).

Subsequently, as shown in FIG. 10C, pressures are applied to the contact boundary surfaces of the first welding portion 11 and the second welding portion 24 in the upward and downward directions (pressure application step). In the pressure application step, the one end portion side of the second resin member 2 is warped along the first welding portion 11 from the follow-up origins 25a and 25 inside the recess grooves 26a and 26 so that the gap between the contact boundary surfaces that is generated owing to the curved recess 12 in the first welding portion 11 is eliminated.

Finally, as shown in FIG. 10D, laser light is applied from the second resin member 2 side to the first welding portion 11 so that the first welding portion 11 is welded to the second welding portion 24 (laser light application step). Since there is no gap between the contact boundary surfaces 3 of the first welding portion 11 and the second welding portion 24, heat of the laser light is transmitted to the second welding portion 24, whereby normal welding can be performed.

In embodiment 4, the follow-up origin 25 can be provided and the same advantageous effects as those in the above embodiment 1 are obtained, without forming the thin portion 22. In addition, by providing the plurality of recess grooves 26a and 26, improvement in the follow-up capability of the second resin member 2 is achieved.

### Embodiment 5

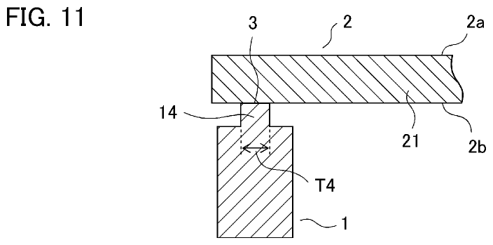

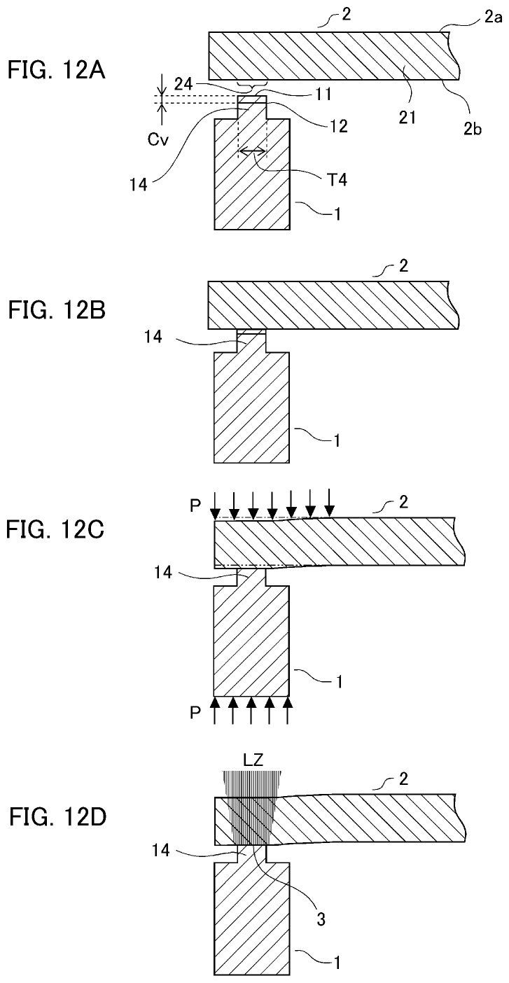

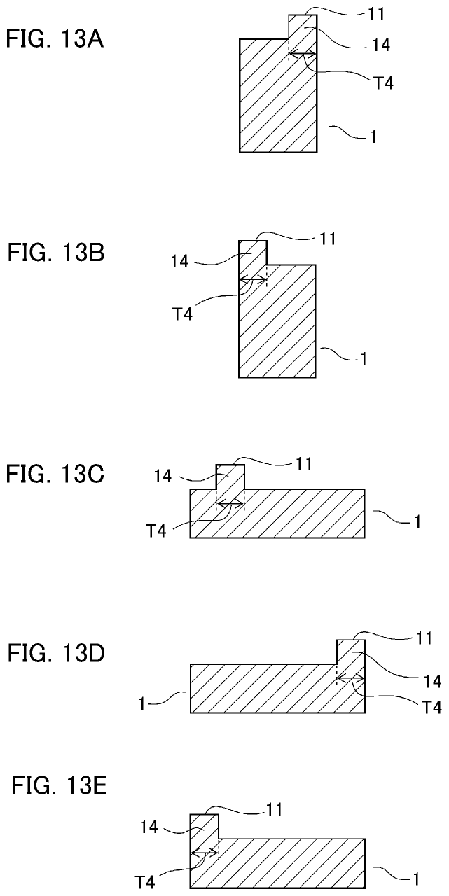

FIG. 11 is a cross-sectional view showing a resin member joint structure according to embodiment 5. FIGS. 12A to 12D are cross-sectional views for explaining a laser welding method according to embodiment 5. FIGS. 13A to 13E are cross-sectional views showing modifications of the resin member joint structure according to embodiment 5.

The first resin member 1 and the second resin member 2 are joined together through laser welding. The first resin member 1 has laser light absorbing property, and the second resin member 2 has laser light transmitting property. The first resin member 1 and the second resin member 2 are not particularly limited in terms of uses thereof and are used for, for example, forming a box-shaped housing in which an electrical part is accommodated.

The first resin member 1 includes, on the one end portion thereof, a rib 14 projecting in a direction toward the second resin member 2, and includes the first welding portion 11 at a top portion of the rib 14. The second resin member 2 includes the plate-shaped portion 21 which has the two main surfaces 2a and 2b opposite to each other. The second welding portion 24 to be joined to the first welding portion 11 is located at the one end portion of the one main surface 2b.

By thus using the top portion of the rib 14 of the first resin member 1 as the first welding portion 11, a width T4, i.e., a laser welding width, of the first welding portion 11 can be decreased. Consequently, the follow-up capability exhibited when the second resin member 2 is fitted along the first welding portion 11, is improved so that the advantageous effect of decreasing the gap between the contact boundary surfaces 3 can be expected to be obtained. In addition, if the width T4 of the first welding portion 11 is small, an advantageous effect of decreasing the dimension Cv of the curved recess 12 in the first welding portion 11 is also obtained.

The laser welding method according to embodiment 5 will be described with reference to FIGS. 12A to 12D. As shown in FIG. 12A, the first resin member 1 including the first welding portion 11 at the top portion of the rib 14, and the second resin member 2 including the plate-shaped portion 21, are prepared. Here, the curved recess 12 having the dimension Cv is assumed to be present in the surface of the first welding portion 11.

Next, as shown in FIG. 12B, the second welding portion 24 of the second resin member 2 is disposed on the upper side of the first welding portion 11, to be brought into contact with the said upper side (contact step). Subsequently, as shown in FIG. 12C, pressures are applied to the contact boundary surfaces of the first welding portion 11 and the second welding portion 24 in the upward and downward directions (pressure application step). In the pressure application step, the one end portion side of the second resin member 2 is warped along the first welding portion 11 so that the gap between the contact boundary surfaces that is generated owing to the curved recess 12 in the first welding portion 11 is eliminated. Since the first welding portion 11 is provided at the top portion of the rib 14, the width of the contact boundary surface is decreased, and follow-up by the second resin member 2 is easily achieved.

Finally, as shown in FIG. 12D, laser light is applied from the second resin member 2 side to the first welding portion 11 so that the first welding portion 11 is welded to the second welding portion 24 (laser light application step). Since there is no gap between the contact boundary surfaces 3 of the first welding portion 11 and the second welding portion 24, heat of the laser light is transmitted to the second welding portion 24, whereby normal welding can be performed.

Modifications of the resin member joint structure according to embodiment 5 will be described with reference to FIGS. 13A to 13E. The position of the rib 14 is not particularly limited as long as the rib 14 is provided on the one end portion of the first resin member 1. As shown in FIG. 13A and FIG. 13B, the rib 14 may be provided so as to be contiguous with the inner end surface or an outer end surface of the first resin member 1. If the one end portion of the first resin member 1 on which the rib 14 is provided has a large area as shown in FIG. 13C, FIG. 13D, and FIG. 13E, the advantageous effect obtained by providing the rib 14 is particularly exhibited.

In embodiment 5, the top portion of the rib 14 projecting from the one end portion of the first resin member 1 is used as the first welding portion 11 so that the width of the first welding portion 11 can be decreased. Thus, the one end portion side of the second resin member 2 on which the second welding portion 24 is located, is easily fitted along the first welding portion 11 of the first resin member 1. Consequently, the gap between the contact boundary surfaces 3 of the first welding portion 11 and the second welding portion 24 can be eliminated, whereby imperfection of welding can be ameliorated.

Although the resin member joint structure according to embodiment 5 exhibits the advantageous effects of improving the follow-up capability of the second resin member 2 and decreasing the gap between the contact boundary surfaces 3 even if the said resin member joint structure is used singly, the above advantageous effects are further increased by combination with the above embodiments 1 to 4.

### Embodiment 6

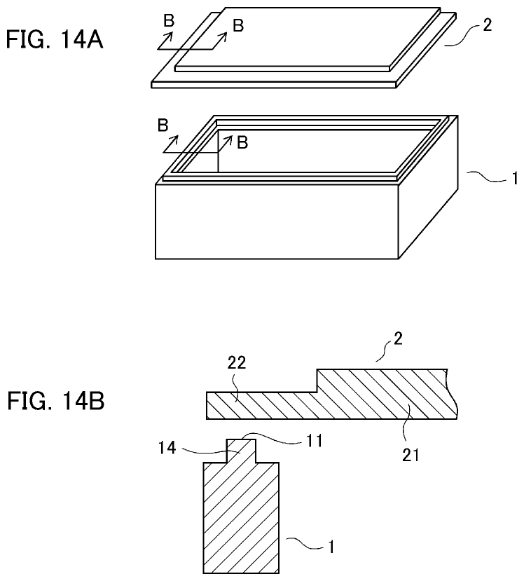

In embodiment 6, a box-shaped resin housing having the resin member joint structure according to any of the above embodiments 1 to 5 will be described by presenting specific examples thereof. FIGS. 14A, 15A, 16A, 17A, and 18A are perspective views and FIGS. 14B, 15B, 16B, 17B, and 18B are partial cross-sectional views showing box-shaped resin housings according to embodiment 6. FIG. 14B is a cross-sectional view taken at a position indicated by B-B in FIG. 14A.

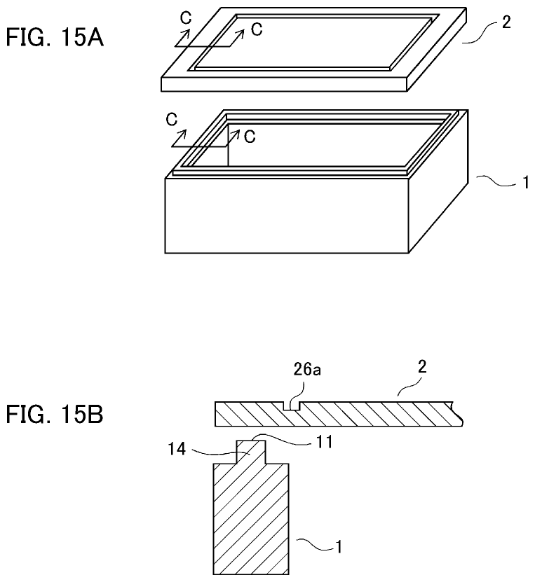

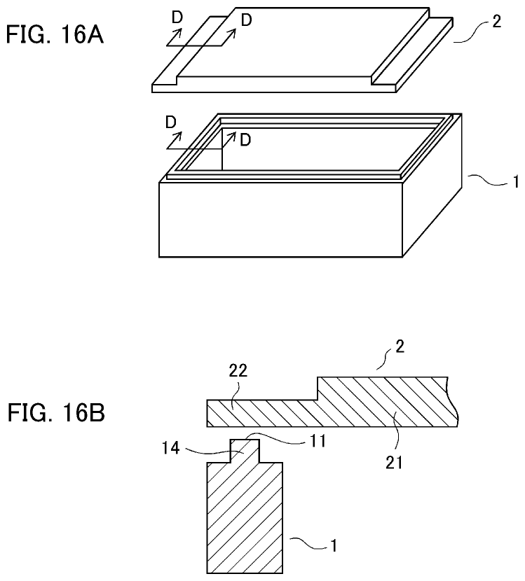

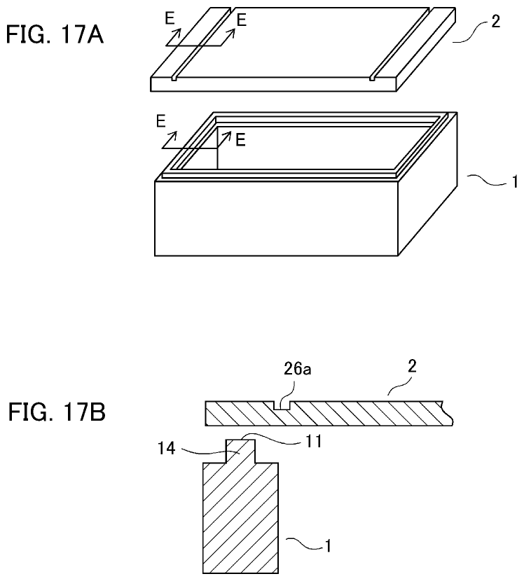

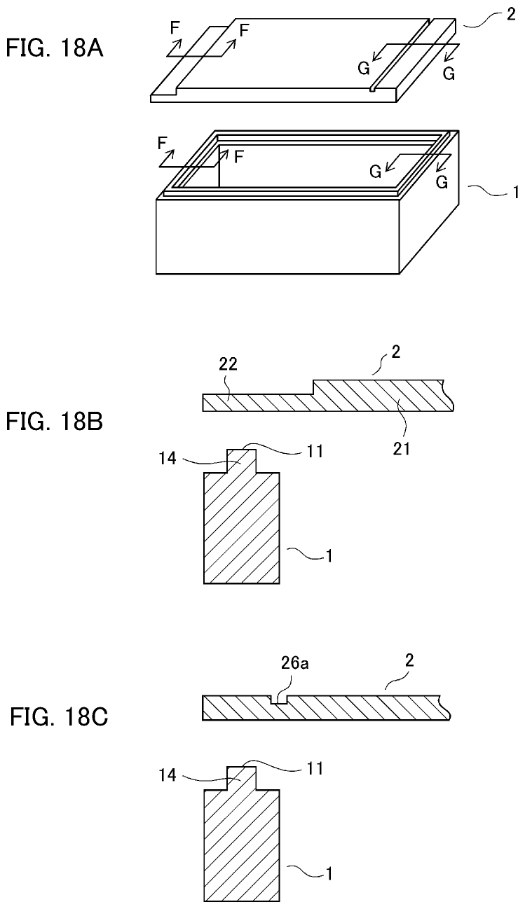

Likewise, FIG. 15B is a cross-sectional view taken at a position indicated by C-C in FIG. 15A, FIG. 16B is a cross-sectional view taken at a position indicated by D-D in FIG. 16A, and FIG. 17B is a cross-sectional view taken at a position indicated by E-E in FIG. 17A. FIG. 18B and FIG. 18C are cross-sectional views respectively taken at positions indicated by F-F and G-G in FIG. 18A.

FIGS. 14A and 14B illustrate a combination between the first resin member 1 including the rib 14 and the second resin member 2 including the thin portion 22. FIGS. 15A and 15B illustrate a combination between the first resin member 1 including the rib 14 and the second resin member 2 including the recess groove 26a. In FIGS. 14A and 14B and FIGS. 15A and 15B, each of the rib 14, the thin portion 22, and the recess groove 26a are provided at an outer peripheral portion of the box-shaped housing.

Alternatively, each of the thin portion 22, the recess groove 26a, and the like may be partially provided at locations at which the follow-up capability is desired to be improved. FIGS. 17A and 17B, the rib 14 is provided on an outer peripheral portion of the first resin member 1, and the thin portion 22 is provided to each of two end surfaces of the second resin member 2 that are opposite to each other. Likewise, in FIGS. 17A and 17B, the rib 14 is provided on the outer peripheral portion of the first resin member 1, and the recess groove 26a is provided near each of the two end surfaces of the second resin member 2 that are opposite to each other. Although the thin portion 22 and the recess groove 26a are provided on a shorter side of the box-shaped housing in FIGS. 16A and 16B and FIGS. 17A and 17B, the thin portion 22 and the recess groove 26a may be provided on a longer side thereof.

FIGS. 18A and 18B, the rib 14 is provided on the outer peripheral portion of the first resin member 1, the thin portion 22 is provided to one of the two end surfaces of the second resin member 2 that are opposite to each other, and the recess groove 26a is provided near the other end surface. In this manner, the thin portion 22 and the recess groove 26a can be used in combination in one box-shaped housing.

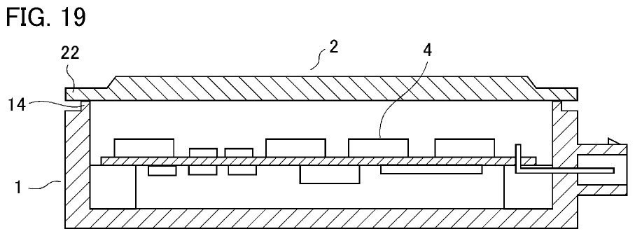

FIG. 19 is a cross-sectional view showing a resin housing of electrical equipment according to embodiment 6, in which the resin member joint structure according to the present disclosure has been applied to the outer peripheral portion of the resin housing of electrical equipment. The resin housing includes: the first resin member 1 including the rib 14; and the second resin member 2 having the thin portion 22. The resin housing accommodates therein an electrical part 4. For example, if the electrical equipment is a millimeter wave radar module, the electrical part 4 includes: a high-frequency circuit for outputting a transmission wave that is a millimeter wave; a transmission/reception antenna; a signal processing circuit; and the like.

In embodiment 6, the resin member joint structure according to any of the above embodiments 1 to 5 has been applied to the resin housing of electrical equipment. Consequently, imperfection of welding in the resin housing is ameliorated, whereby quality improvement is achieved.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the specification of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 first resin member
2 second resin member
2a, 2b main surface
3 contact boundary surface
4 electrical part
11 first welding portion
12 curved recess
13 inner end surface
14 rib
21 plate-shaped portion
22 thin portion
23 end surface
24 second welding portion
25, 25a follow-up origin
26, 26a, 26b, 26c, 26d recess groove

1. A resin member joint structure in which a first resin member and a second resin member have been joined together through welding, wherein
the first resin member includes a first welding portion,
the second resin member includes a plate-shaped portion which has two main surfaces opposite to each other,
a second welding portion joined to the first welding portion is located at one end portion of one main surface out of the main surfaces, and
a follow-up origin is provided on one or each of the two main surfaces of the second resin member such that, from the follow-up origin, the one end portion side on which the second welding portion is located is warped along the first welding portion.

2. The resin member joint structure according to claim 1, wherein
the second resin member includes, on the one end portion side of the plate-shaped portion, a thin portion having a plate thickness smaller than a plate thickness of another portion of the plate-shaped portion,
the second welding portion is located in the thin portion, and
the follow-up origin is present at a boundary between the thin portion and the other portion.

3. The resin member joint structure according to claim 2, wherein if
the plate thickness of the thin portion of the plate-shaped portion is defined as T1, and
the plate thickness of the other portion is defined as T2, T1≤T2×2/3 is satisfied.

4. The resin member joint structure according to claim 2, wherein
if, in a plane parallel to the main surfaces of the second resin member,
a direction from a center side of the second resin member toward the one end portion side is defined as an X direction,
a distance from the follow-up origin to the first resin member is defined as L1, and
a width in the X direction of the first welding portion is defined as T3, L1≥T3 is satisfied.

5. The resin member joint structure according to claim 1, wherein
the second resin member includes a recess groove in one or each of the two main surfaces,
the recess groove is located at a position that is farther from the one end portion than the second welding portion is, and
the follow-up origin is present inside the recess groove.

6. The resin member joint structure according to claim 5, wherein
if, in a plane parallel to the main surfaces of the second resin member,
a direction from a center side of the second resin member toward the one end portion side is defined as an X direction,
a distance from the follow-up origin to the first resin member is defined as L2, and
a width in the X direction of the first welding portion is defined as T3, L2≥T3 is satisfied.

7. The resin member joint structure according to claim 5, wherein the recess groove is provided at each of two or more positions in either one or each of the two main surfaces.

8. The resin member joint structure according to claim 1, wherein the first resin member includes, on one end portion thereof, a rib projecting in a direction toward the second resin member, and includes the first welding portion at a top portion of the rib.

9. A resin member joint structure in which a first resin member and a second resin member have been joined together through welding, wherein
the first resin member includes, on one end portion thereof, a rib projecting in a direction toward the second resin member, and includes a first welding portion at a top portion of the rib,
the second resin member includes a plate-shaped portion which has two main surfaces opposite to each other, and
a second welding portion joined to the first welding portion is located at one end portion of one main surface out of the main surfaces.

10. The resin member joint structure according to claim 1, wherein
the first resin member has laser light absorbing property, and
the second resin member has laser light transmitting property.

11. The resin member joint structure according to claim 1, the first resin member and the second resin member forming a box-shaped housing.

12. The resin member joint structure according to claim 11, the box-shaped housing accommodating therein an electrical part.

13. The resin member joint structure according to claim 12, wherein the electrical part is a millimeter wave radar.

14. A resin housing of electrical equipment, the resin housing having the resin member joint structure according to claim 1, the resin housing comprising:
the first resin member; and
the second resin member, wherein
electrical equipment is accommodated.

15. A laser welding method for joining together a first resin member having laser light absorbing property and a second resin member having laser light transmitting property through laser welding, the laser welding method comprising:
preparing the first resin member including a first welding portion and the second resin member including a plate-shaped portion which has two main surfaces opposite to each other, and
placing, on an upper side of the first welding portion, a second welding portion located at one end portion of one main surface out of the main surfaces of the second resin member, to bring the second welding portion into contact with the upper side;
applying pressures to contact boundary surfaces of the first welding portion and the second welding portion in upward and downward directions; and
applying laser light to the first welding portion from the second resin member side, to weld the first welding portion to the second welding portion, wherein
warping, along the first welding portion, the one end portion side of the second resin member such that the warping occurs from a follow-up origin provided on one or each of the two main surfaces, to eliminate a gap between the contact boundary surfaces, when applying the pressure.

16. The laser welding method according to claim 15, wherein
the second resin member includes, on the one end portion side of the plate-shaped portion, a thin portion having a plate thickness smaller than a plate thickness of another portion of the plate-shaped portion,
the second welding portion is located in the thin portion, and
the follow-up origin is present at a boundary between the thin portion and the other portion.

17. The laser welding method according to claim 15, wherein
the second resin member includes a recess groove in one or each of the two main surfaces,
the recess groove is located at a position that is farther from the one end portion than the second welding portion is, and
the follow-up origin is present inside the recess groove.

18. The laser welding method according to claim 15, wherein the first resin member includes, on one end portion thereof, a rib projecting in a direction toward the second resin member, and includes the first welding portion at a top portion of the rib.

19. The laser welding method according to claim 15,
the first resin member and the second resin member forming a box-shaped housing,
the laser welding method being applied to welding outer peripheral portions of the box-shaped housing.
